(19) United States
(12) Patent Application Publication
(10) Pub. No.: US 2025/0212692 A1
(43) Pub. Date: Jun. 26, 2025

(54) MAGNETOSTRICTIVE MATERIAL AND ELEMENT CONTAINING SAME

(71) Applicant: OSAKA UNIVERSITY, Suita-shi, Osaka (JP)

(72) Inventors: Shun FUJIEDA, Suita-shi, Osaka (JP); Takashi NAKAGAWA, Suita-shi, Osaka (JP); Miu HISAMATSU, Suita-shi, Osaka (JP)

(21) Appl. No.: 18/851,371

(22) PCT Filed: Feb. 2, 2023
(86) PCT No.: PCT/JP2023/003475

§ 371 Date: Sep. 26, 2024

(30) Foreign Application Priority Data
Mar. 28, 2022 (JP) 2022-052449

(51) Int. Cl. H10N 35/85; C01G 51/00; C04B 35/26; H01F 1/03; H10N 35/01

(52) U.S. Cl. CPC H10N 35/85; C01G 51/00; C04B 35/26; H01F 1/03; H10N 35/01

(57) ABSTRACT

Provided is a novel magnetostrictive material that has a high level of magnetostrictive properties without containing rare-earth elements. The magnetostrictive material contains a copper cobalt ferrite that contains a cubic crystal as a primary crystalline phase.

### TECHNICAL FIELD

The present invention relates to a magnetostrictive material and an element containing the magnetostrictive material.

### BACKGROUND ART

Magnetostrictive materials have magnetic properties called “magnetostriction.” Magnetostriction refers to the distortion (strain) of a crystal lattice depending on the direction of magnetic moment. Magnetostrictive materials change their length when a magnetic field is applied without contact, which is called a “magnetostriction effect” (Joule effect). Additionally, magnetostrictive materials undergo a change in magnetization when compressed and exhibit a change in magnetic permeability, which is called an “inverse magnetostriction effect” (Villari effect). For example, magnetostrictive materials are currently used in transducers of ultrasonic generators or fish finders, actuators, etc. due to the magnetostriction effect. Magnetostrictive materials are also used in sensors, vibration-powered generators, etc. due to the inverse magnetostriction effect.

A wide range of magnetic materials are known from metal-based and alloy-based materials to metal oxide-based materials. In particular, it is generally known that materials containing rare earth have a higher magnetostriction constant than other materials. However, the supply risk of rare earth makes it unsuitable for high-volume and low-cost production. It is also stated that materials containing rare earth have poor mechanical properties, imposing many restrictions on their industrial application, such as the need for high-quality monocrystals.

### CITATION LIST

### Non-Patent Literature

NPL 1: A. E. Clark, Extraordinary magnetoelasticity and lattice softening in bcc Fe—Ga alloys, 2003, Journal of Applied Physics 93, 8621

### SUMMARY OF INVENTION

### Technical Problem

Therefore, there is demand for the development of novel, rare-earth-free materials that have a high level of magnetostrictive properties.

### Solution to Problem

The present inventors conducted extensive research to solve the problems above and found that among various copper cobalt ferrites, those with a cubic crystal as the primary crystalline phase have a high level of magnetostrictive properties despite being rare-earth-free. The inventors conducted further study based on the finding and completed the present invention, which includes the following aspects.

### Item 1

A magnetostrictive material comprising a copper cobalt ferrite containing a cubic crystal as a primary crystalline phase.

### Item 2

The magnetostrictive material according to Item 1, wherein the copper cobalt ferrite consists essentially of a cubic phase.

### Item 3

The magnetostrictive material according to Item 1 or 2, wherein the copper cobalt ferrite is represented by CuₓCo_{y-x}Fe_{3-y}O₄ (0<x/y≤0.75 and 0.8≤y≤1.2), with the proviso that one or more elements among Co, Fe, and Cu may further be partially substituted with one or more other elements.

### Item 4

The magnetostrictive material according to any one of Items 1 to 3, which is a polycrystal or a monocrystal.

### Item 5

The magnetostrictive material according to Item 4, wherein the polycrystal is a non-oriented polycrystal.

### Item 6

The magnetostrictive material according to Item 4, wherein the polycrystal is a crystallographically oriented polycrystal.

### Item 7

An element being operative by using a magnetostriction effect or an inverse magnetostriction effect of the magnetostrictive material of any one of Items 1 to 6.

### Item 8

The element according to Item 7, which is a transducer, an actuator, a sensor, or a vibration-powered generator.

### Item 9

A method for operating an element containing the magnetostrictive material of any one of Items 1 to 6, comprising the step of operating the element by using a magnetostriction effect or an inverse magnetostriction effect of the magnetostrictive material.

### Item 10

A method for producing a copper cobalt ferrite containing a cubic crystal as a primary crystalline phase, comprising the step of producing the copper cobalt ferrite by using iron oxide, copper oxide, and cobalt oxide as starting materials.

### Item 11

The method according to Item 10,
wherein the copper cobalt ferrite is represented by a chemical formula: CuₓCo_{y-x}Fe_{3-y}O₄ (0<x/y≤0.75 and 0.8≤y≤1.2), with the proviso that one or more elements among Co, Fe, and Cu may further be partially substituted with one or more other elements,
the method further comprising the step of adjusting the molar ratio of the starting materials to a stoichiometric composition based on the chemical formula to obtain the copper cobalt ferrite.

### Advantageous Effects of Invention

The present invention provides a novel magnetostrictive material that has a high level of magnetostrictive properties without containing rare-earth elements.

### BRIEF DESCRIPTION OF DRAWINGS

FIG. 1 is a drawing showing a method in Examples.

FIG. 2 is a drawing showing a method in Examples.

FIG. 3 is a drawing showing a method in Examples.

FIG. 4 is a drawing showing a method in Examples.

FIG. 5 is a drawing showing the results of Examples.

FIG. 6 is a drawing showing the results of Examples.

FIG. 7 is a drawing showing the results of Examples.

FIG. 8 is a drawing showing the results of Examples.

FIG. 9 is a drawing showing the results of Examples.

FIG. 10 is a drawing showing the results of Examples.

FIG. 11 is a drawing showing the results of Examples.

FIG. 12 is a drawing showing the results of Examples.

FIG. 13 is a drawing showing the results of Examples.

FIG. 14 is a drawing showing the results of Examples.

FIG. 15 is a drawing showing the results of Examples.

FIG. 16 is a drawing showing the results of Examples.

FIG. 17 is a drawing showing the results of Examples.

FIG. 18 is a drawing showing the results of Examples.

FIG. 19 is a drawing showing the results of Examples.

FIG. 20 is a drawing showing the results of Examples.

FIG. 21 is a drawing showing the results of Examples.

FIG. 22 is a drawing showing the results of Examples.

FIG. 23 is a drawing showing the results of Examples.

FIG. 24 is a drawing showing the results of Examples.

FIG. 25 is a drawing showing the results of Examples.

FIG. 26 is a drawing showing the results of Examples.

FIG. 27 is a drawing showing the results of Examples.

FIG. 28 is a drawing showing the results of Examples.

FIG. 29 is a drawing showing the results of Examples.

FIG. 30 is a drawing showing the results of Examples.

FIG. 31 is a drawing showing the results of Examples.

FIG. 32 is a drawing showing the results of Examples.

FIG. 33 is a drawing showing the results of Examples.

FIG. 34 is a drawing showing the results of Examples.

FIG. 35 is a drawing showing the results of Examples.

### DESCRIPTION OF EMBODIMENTS

### 1. Magnetostrictive Material

The magnetostrictive material of the present invention contains a copper cobalt ferrite that has a cubic crystal as a primary crystalline phase.

The copper cobalt ferrite has a spinel structure. The spinel structure contains 32 oxygen atoms that form a face-centered cubic lattice in the unit lattice, with 8 metal atoms occupying the lattice A position (tetrahedrally 4-coordinated position) and 16 metal atoms occupying the lattice B position (octahedrally 6-coordinated position).

Without wishing to be bound by theory, it is believed that the magnetostrictive material of the present invention exhibits a high level of magnetostrictive properties due to the fact that the copper cobalt ferrite has a cubic crystal as its primary crystalline phase. The present inventors discovered that a copper cobalt ferrite that contains a cubic crystal as its primary crystalline phase has a higher level of magnetostrictive properties than a copper cobalt ferrite that contains a single phase of a tetragonal crystal system as a crystalline phase. Thus, the magnetostrictive material of the present invention may be a mixture of a cubic phase and a heterophase as long as the copper cobalt ferrite contains a cubic crystal as a primary crystalline phase.

The cubic phase of the copper cobalt ferrite may be a single phase, or composed of two or more types of cubic phases.

From the viewpoint of exhibiting a higher level of magnetostrictive properties, the copper cobalt ferrite preferably consists essentially of a cubic phase, and more preferably consists of a cubic phase.

In the present invention, the copper cobalt ferrite preferably has a magnetostriction constant λₛ (10000 Oₑ) of −200 ppm or less, more preferably −250 ppm or less, and still more preferably −300 ppm or less.

In the present invention, magnetostriction constant λₛ (10000 Oₑ) is determined according to magnetostriction measurement at an applied magnetic field of −10000≤H(Oe)≤10000. Specifically, magnetostriction constant λₛ (10000 Oe) is calculated as explained below (reference: Hiroshi Shimada, and three others, Jiseizairyo—Bussei Kogakutokusei to Sokuteiho [Magnetic Materials—Physical and Engineering Properties and Measurement Methods], 1999, Kodansha Scientific, pp. 136-143, p. 296).

In the case of a polycrystal, if the angle made by the direction of an applied magnetic field and the direction of strain measurement is θ, the strain is expressed by the following equation.

$$\frac{Δ l}{l} = \frac{3}{2} {λ}_{s} ( {cos}^{2} θ - \frac{1}{3} )$$

Due to θ being 0, strain λ₈₁ in the direction parallel to the direction of the applied magnetic field is expressed by the following:

λ_{∥}=λₛ

Due to θ being π/2, the strain perpendicular to the direction of the applied magnetic field

λ_{⊥}

is expressed by the following:

$${λ}_{⊥} = - \frac{{λ}_{s}}{2}$$

Thus, magnetostriction constant λₛ can be expressed using

λ_{∥},λ_{⊥}

by the following equation:

$${λ}_{s} = \frac{2}{3} ( {λ}_{∥} - {λ}_{⊥} )$$

By using data of

λ_{∥},λ_{⊥}

at an applied magnetic field of 10000 Oₑ, magnetostriction constant λₛ (10000 Oₑ) can be determined.

In the present invention, the crystalline phase of a copper cobalt ferrite is identified by indexing a diffraction pattern obtained by X-ray diffraction measurement in the range of, for example, 25≤2θ (degrees)≤45.

The copper cobalt ferrite for use in the present invention is CoFe₂O₄ in which at least Co is partially substituted with Cu. The copper cobalt ferrite for use in the present invention also includes those in which one or more elements among Co, Fe, and Cu are partially substituted with one or more other elements. In the above, examples of other elements include, but are not particularly limited to, Li, Na, Mg, Al, Si, Ca, Sc, Ti, V, Cr, Mn, Ni, Zn, Ga, Ge, Sr, Y, Zr, Nb, Mo, Rh, Ag, Cd, In, Sn, Sb, Ba, Hf, Ta, W, La, Ce, Pr, Nd, Sm, Eu, Gd, Tb, Dy, Ho, Er, Tm, Yb, and Lu. For other elements, Ti, Mn, and Zn are particularly preferred.

In the present invention, the copper cobalt ferrite is preferably represented by CuₓCo_{y-x}Fe_{3-y}O₄ (0<x/y≤0.75 and 0.8≤y≤1.2). A ratio of x to y (x/y) within this specific range allows the crystalline phase of the copper cobalt ferrite to form as described above, resulting in a high level of magnetostrictive properties. In this regard, x/y is preferably 0.7 or less, and more preferably 0.65 or less. A ratio of 0<x/y≤0.6 tends to give a crystalline phase composed of only a cubic phase. From the viewpoint of a high level of magnetostrictive properties, x/y is more preferably 0.2 or more and 0.6 or less, and still more preferably 0.3 or more and 0.6 or less. However, copper cobalt ferrites represented by CuₓCo_{y-x}Fe_{3-y}O₄ (0<x/y=0.75 and 0.8≤y≤1.2) in which one or more elements among Co, Fe, and Cu are partially substituted with one or more other elements as mentioned above are also preferably used for the same reason.

In the above, y is preferably 0.85$y$1.15, more preferably 0.9≤y≤1.1, and most preferably y=1.

The copper cobalt ferrite can be prepared according to, for example, a solid-state reaction method, a sol-gel method, or a flux method.

In the solid-state reaction method, the value of x can be adjusted accordingly by adjusting the stoichiometric composition for the starting materials. For example, the molar ratio of starting materials, a-iron (III) oxide (a-Fe₂O₃), copper (I) oxide (Cu₂O), and cobalt (II) oxide (CoO) are adjusted to a stoichiometric composition such that the value of x is a desired value to thereby obtain a copper cobalt ferrite for use in the present invention. For example, in the solid-state reaction method, the copper cobalt ferrite for use in the present invention can be obtained by mixing and pulverizing the starting materials adjusted as described above in an aqueous solution and then calcining the pulverized material.

In the production method described above, the starting materials may be mixed and pulverized, for example, in ultrapure water.

In the production method described above, the starting material may be pulverized, for example, in a ball mill.

After the starting materials are mixed and pulverized, the pulverized mixture may be optionally filtered before calcination. After filtration, the filtrate may also be further dried and pulverized. The pulverization may be performed by using a mortar, for example.

In the sol-gel method, the value of x can be adjusted as appropriate by adjusting the concentration of the metal salt to be dissolved in the aqueous solution. For example, iron nitrate, cobalt nitrate, and copper nitrate are dissolved in a citric acid solution, and ethylene glycol is added thereto, followed by heating the mixture to form a gel. The gel is then further heated to obtain a powdery precursor of a copper cobalt ferrite.

Before calcination, the thus-obtained pulverized material and the powdery precursor are preferably pelletized. Although the means of pelleting is not particularly limited, a press machine or a similar machine can be used.

Sintering conditions are not particularly limited. For example, the retention temperature may be 700° C. or higher, preferably 750° C. or higher and 1200° C. or lower, and more preferably 800° C. or higher and 1000° C. or lower. For example, the retention time may be 2 hours or longer in air atmosphere. More specific conditions are, for example, the following: a retention temperature of 950° C., a retention time of 20 hours, and air atmosphere.

In the production method described above, the sintered product may be further optionally pulverized. The pulverization may be performed by using a mortar, for example.

The copper cobalt ferrite may be a polycrystal or a monocrystal.

The polycrystalline copper cobalt ferrite has no crystalline orientation or has crystalline orientation. Non-oriented polycrystalline copper cobalt ferrites are obtained, for example, by simply pulverizing the sintered product and compacting and molding the obtained powder sample.

Crystallographically oriented, polycrystalline copper cobalt ferrites are obtained, for example, by compacting and molding a powder sample obtained by pulverizing the sintered product in a magnetic field. The magnetic field is preferably a unidirectional magnetic field or a rotating magnetic field. The specific method for compacting and molding a powder sample in a unidirectional magnetic field or in a rotating magnetic field is not particularly limited, but may be, for example, the method used in the Examples.

Crystallographically oriented, polycrystalline copper cobalt ferrites are preferred because of their improved magnetostrictive properties.

### 2. Element

The element of the present invention is an element that operates by using the magnetostriction effect or inverse magnetostriction effect of the magnetostrictive material of the present invention. Specifically, examples of elements include transducers, actuators, sensors, and vibration-powered generators.

Examples of transducers include transducers for ultrasonic generators and fish finders.

Actuators use the magnetostriction effect (Joule effect). Actuators obtain displacement or a driving force due to a magnetic field.

Sensors use the inverse magnetostriction effect (Villari effect). Sensors convert a change in magnetic permeability due to application of stress to a magnetostrictive material into a change in inductance of an excitation coil (a change in coil impedance) to sense a force or displacement (the amount of movement of an object).

Vibration-powered generators use the inverse magnetostriction effect (Villari effect). Vibration-powered generators obtain an induced electromotive force from a change in magnetic permeability due to application of stress to a magnetostrictive material wound with a coil according to Faraday's laws of electromagnetic induction.

### EXAMPLES

The present invention is described below with reference to Examples. However, the invention is not limited to these Examples.

### Example 1

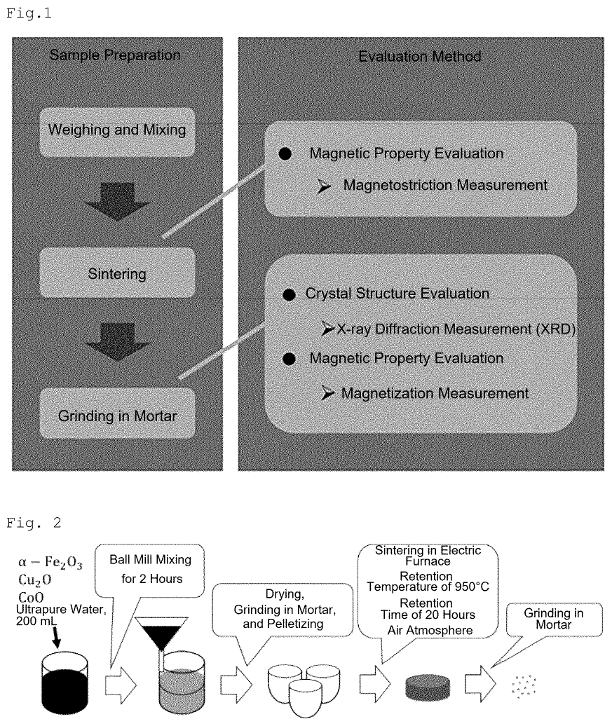

Production of Copper Cobalt Ferrite of Present Invention FIG. 1 shows a general procedure of how to prepare a sample and evaluation. As shown in FIG. 1, after the starting materials were weighed and mixed, the sample was sintered into disk-shaped pellets. The pellets were directly measured for magnetostriction. X-ray diffraction measurement and magnetization measurement were performed with samples prepared by pulverizing the pellets in a mortar. Each measurement is discussed in detail in the sections below.

To obtain desired CuₓCo₁₋ₓFe₂O₄, α-Fe₂O₃, Cu₂O, and CoO were used as starting materials. CoO with a purity of at least 90.0% was used. Table 1 shows the actually used starting materials.

TABLE 1

| Starting Material | Chemical Formula | Supplier | Standard Value |
|---|---|---|---|
| α-Iron(III) Oxide | α-Fe₂O₃ | Rare Metallic Co., Ltd. | 99.999% |
| Copper(I) Oxide | Cu₂O | Wako Pure Chemical | 99.5% or higher |
| | | Industries, Ltd. | |
| Cobalt(II) Oxide | CoO | Wako Pure Chemical | 90.0% or higher |
| | | Industries, Ltd. | |

L

FIG. 2 shows the procedure of sample preparation, and Table 2 summarizes the stoichiometric composition of the prepared samples, α-Fe₂O₃, Cu₂O, and CoO were weighed so as to have a molar ratio in line with the stoichiometric composition shown in Table 2. The weighed sample, together with zirconia balls and 200 mL of ultrapure water, was placed in a ball mill container made of Teflon (registered trademark), and mixed and pulverized for 2 hours using a pot mill rotating table (Nitto Kagaku Co., Ltd., ANZ-51S). Thereafter, filtration was performed, and the sample on filter paper was taken, dried, and ground with an agate mortar. The ground sample was then pressed into pellets (diameter: 10 mm, thickness: about 2.4 mm) with a manual 100 kN mighty press (MT-100H, NPa System, Co., Ltd.) and sintered in an electric furnace (AS ONE Corporation, high-performance muffle furnace, model number: HPM-0N). The pellets were sintered under the following conditions: air atmosphere, heating time of 5 hours, retention time of 20 hours, cooling time of 5 hours, and sintering temperature of 950° C.

TABLE 2
Stoichiometric Composition

CuₓCo₁₋ₓFe₂O₄
(x = 0.0, 0.1, 0.2, 0.3, 0.4, 0.5, 0.6, 0.7, 0.8. 0.9, 1.0)

The crystalline structure of the obtained sintered powder was identified by X-ray diffraction (XRD). The atoms and ions in the crystal were three-dimensionally arranged in a regular manner. X-ray diffraction measurement is a method of identifying a crystalline structure by irradiating a crystalline powder sample with X-rays of a predetermined wavelength to intensify scattered waves at an angle of incidence that satisfies the Bragg's reflection condition expressed by Equation (1), and identifying the crystalline structure from the obtained diffraction pattern of X-rays.

$$2 d sin θ = n λ \qquad Equation ( 1 )$$

$${d}_{\sim} : Lattice Spacing , θ : Diffraction Angle ; n : Integer , λ : Wavelength$$

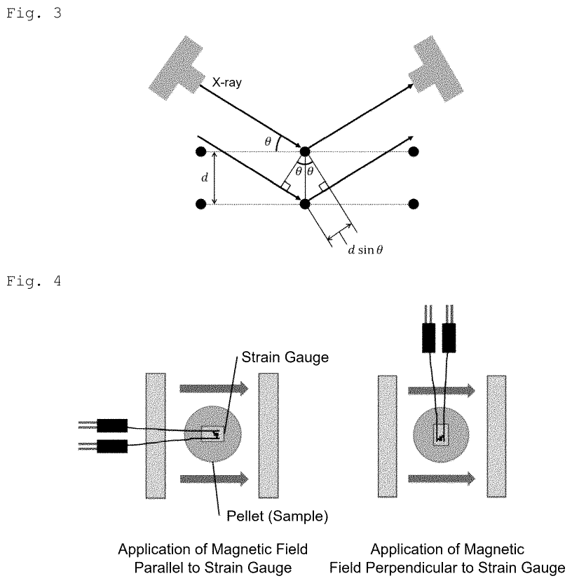

FIG. 3 shows a schematic diagram of X-ray diffraction measurement. The constituent phases of the obtained powder sample were identified by using a Cu-Kα-ray (>=0.1541862 nm) laboratory X-ray diffractometer (Rigaku SmartLab SE diffractometer). The measurements were performed at an acceleration voltage of 40 kV, a target current of 30 mA, a 2θ ranging from 20° to 120°, a step width of 0.02°, and a sweep speed of 2°/min. An X-ray diffraction pattern was obtained by taking the diffraction angle 2θ (degrees) on the horizontal axis and the intensity of diffraction lines (counts per second) on the vertical axis.

The Cohen method (B. D. Cullity, Elements of X-Ray Diffraction, second edition, Addison-Wesley Publishing Company (B. D. Cullity, translated by Gentaro Matsumura, Shinban Cullity X-sen Kaisetsu Yoron, Agune Shofusha (1980), pp. 320-337)) was also used for the diffraction pattern obtained in the measurement to calculate the lattice constant of the sample.

### Magnetization Measurement

Magnetization was measured using a vibrating sample magnetometer (VSM) (Toei Industry Co., Ltd., model number: VSM-C7-10). A VSM measures magnetization by detecting an induced electromotive force generated due to a change in magnetic flux density caused by a magnetic material magnetized when a sample is oscillated at a predetermined period in a uniform magnetic field. In this Example, powder obtained by pulverizing sintered pellets with an agate mortar was packed in a vegetable capsule (Matsuya Corporation, No. 5), which was then attached to a rod to perform measurement (room temperature, maximum applied magnetic field: 10000 Oₑ). The obtained magnetization was converted to a magnetization per unit mass to determine a field-magnetization curve, and saturated magnetization Ms and coercive force Hc were calculated.

### Magnetostriction Measurement

Magnetostriction was measured using a strain gauge (Kyowa Electronic Instruments Co., Ltd., model: KFRB-05-120-C1-11 L1M2R, KFRB-05-120-C1-11 L3M2R) at room temperature under atmospheric pressure by applying a magnetic field of −10000≤H(Oₑ)≤10000 by using the same VSM (Toei Industry Co., Ltd., model number: VSM-C7-10) as that used in magnetization measurement. Similarly, magnetostriction was measured at room temperature by applying a magnetic field of −70000≤H(Oe)≤70000 using a physical property measuring system (PPMS) (Quantum Design, PPMS-KITR). With the PPMS, measurement was performed under two conditions: under atmospheric pressure and under vacuum. Because the strain gauge must be able to expand and contract in unison with an object to be measured, an instant adhesive for strain gauges (Kyowa Electronic Instruments Co., Ltd., model: CC-33A) was used for bonding.

In general, the magnitude of electrical resistance of a metal is inversely proportional to the cross-sectional area and proportional to the length of the metal. Pulling a metal wire decreases the cross-sectional area while increasing the length, thus increasing electrical resistance. Conversely, compressing a metal wire decreases electrical resistance. The elongation and shrinkage of metal are proportional to a change in electrical resistance with a predetermined constant. Because the metal wire bonded to a material to be measured for strain elongates and contracts in accordance with the elongation and contraction of the material, the change in electrical resistance can be measured to determine the elongation and contraction of the material (i.e., strain). Strain was measured when the strain gauge and the applied magnetic field were parallel and when the strain gauge and the applied magnetic field were perpendicular to each other.

To accurately measure the change in electrical resistance of a strain gauge, a bridge circuit is formed to measure the change in electrical resistance by replacing the change in electrical resistance with a change in voltage. Since the magnitude of the voltage is as small as being measurable in microvolts (μV), it is generally amplified by a factor of 5000 to 10000 by using a distortion amplifier. In this Example, a strain gauge was attached to a sample of a disk-shaped pellet (diameter: 10 mm, and thickness: about 2.4 mm), and the pellet was stuck to the rod with double-sided tape. By replacing the double-sided tape for each measurement, measurement was performed for the case in which the direction of magnetic field application and the direction of strain measurement are parallel to each other, i.e., λ_{∥}, and for the case in which the direction of magnetic field application and the direction of strain measurement are perpendicular to each other, i.e.,

λ_{⊥}

FIG. 4 shows an image. Based on these measurements, magnetostriction constant λₛ was calculated, and comparative examination was conducted.

### Crystalline Structure of Prepared Sample

### Crystalline Phase Identification

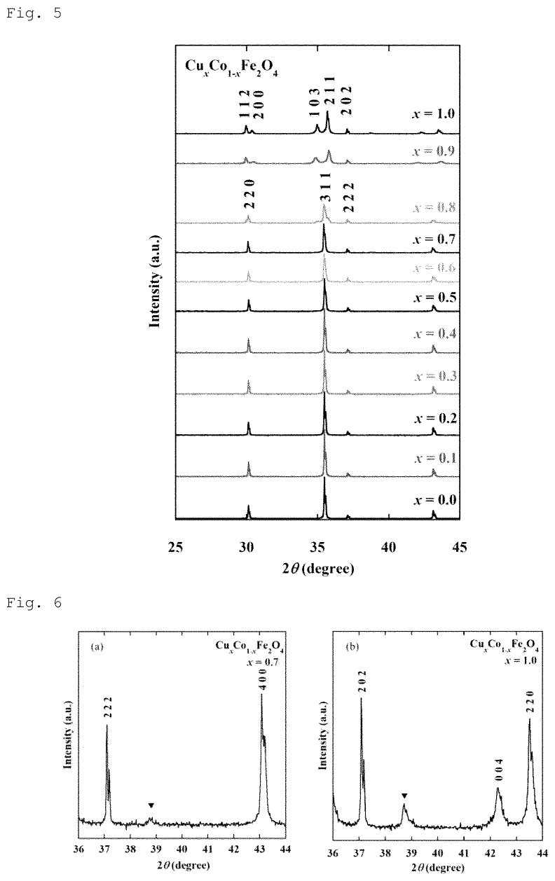

FIG. 5 shows the indexed results of diffraction patterns obtained in X-ray diffraction measurement in the range of 25≤2θ (degrees)≤45. Crystal phase identification revealed that x=0.0 to 0.5 indicates a cubic single phase, and that x=0.9 indicates an almost tetragonal single phase. Between 38° and 39°, x=0.7 and x=1.0 showed a heterophase diffraction peak although it was very low intensity (FIG. 6). Thus, x=0.7 was thought to indicate a two-phase mixture of a cubic phase and a heterophase and x=1.0 was thought to indicate a two-phase mixture of a tetragonal phase and a heterophase.

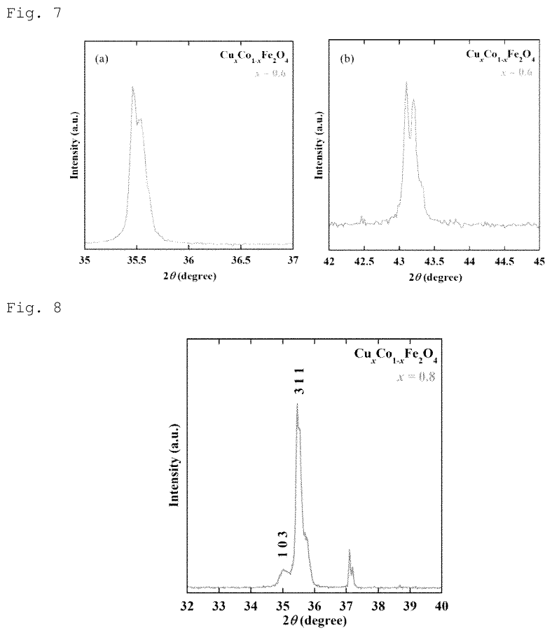

FIG. 7 shows magnified views for X-ray diffraction patterns for x=0.6 in 35≤2θ (degrees)≤37 and 42≤20 (degrees)≤45. The two peaks around 35.5° and 43.2° are unlikely to be K_{α1} and K_{α2} lines in a single diffraction plane because the intensity ratio of the peaks is not 2:1. Additionally, a shoulder that is not fully peaked is seen at both peaks around 35.5° and 43.2°. Thus, x=0.6 is considered to indicate two different cubic phases. FIG. 8 also shows a magnified view of the x-ray diffraction peak for x=0.8 in 32≤2θ (degrees)≤40. Because a (311) diffraction peak of the cubic phase and a (103) diffraction peak of the tetragonal phase were observed around 35.5°, x=0.8 was thought to be present in two phases: a cubic phase and a tetragonal phase.

Tetragonal crystals formed at x=0.9 and 1.0 are due to the Jahn-Teller effect caused by a partial substitution of Cu. The Jahn-Teller effect is a phenomenon in which the loss of elastic energy competes with the gain in energy of the electron system due to distortion, making the distorted one more energetically stable. Since the Jahn-Teller effect is more pronounced in a hexa-coordinated Cu²⁺, the increase in Cu²⁺ entering the reversed spinel-structured lattice B at x=0.9 and 1.0 is thought to have caused the Jahn-Teller effect to form a tetragonal crystal.

### Calculation of Lattice Constant

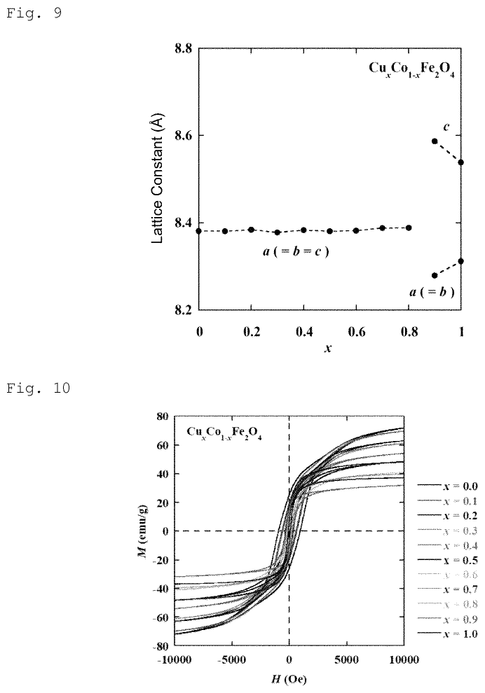

From the patterns obtained in X-ray diffraction measurement, the lattice constant of the major crystalline phases was calculated. FIG. 9 shows the dependence of the lattice constant of CuₓCo₁₋ₓFe₂O₄ on the amount of Cu substitution x. In x≤0.8, in which the major crystalline phase was a cubic phase, there was little dependence of the lattice constant on composition. In x=0.9 and 1.0, in which the major crystalline phase was a tetragonal phase, base edges a and b of the lattice shrank and height c was stretched. The Jahn-Teller effect was speculated to act more strongly at x=1.0, in which the amount of substitution of Cu was larger, resulting in greater square distortion. However, the lattice was found to be distorted to a greater extent at x=0.9. As mentioned above, a heterophase was found to be present at x=1.0. Since this heterophase was related to Cu, it was inferred that the failure of Cu to completely react resulted in a greater lattice constant for x=0.9 than for x=1.0, leading to strain.

Table 3 summarizes the results of the crystalline phase and lattice constant for samples of different compositions.

TABLE 3

Lattice Constant (Å)

| | | | |
|---|---|---|---|
| x | Crystalline Phase | a, b | c |

| | | |
|---|---|---|
| 0.0 | Cubic Phase | 8.382 |
| 0.1 | Cubic Phase | 8.381 |
| 0.2 | Cubic Phase | 8.384 |
| 0.3 | Cubic Phase | 8.378 |
| 0.4 | Cubic Phase | 8.383 |
| 0.5 | Cubic Phase | 8.381 |
| 0.6 | Two Phases of Cubic | 8.382 |
| | Phases | |
| 0.7 | Cubic Phase + | 8.388 |
| | Heterophase | |
| 0.8 | Cubic Phase + | 8.389 |

| | | | |
|---|---|---|---|
| | Tetragonal Phase | | |
| 0.9 | Tetragonal Phase | 8.280 | 8.587 |
| 1.0 | Tetragonal Phase + | 8.312 | 8.538 |
| | Heterophase | | |

### Magnetization Measurement

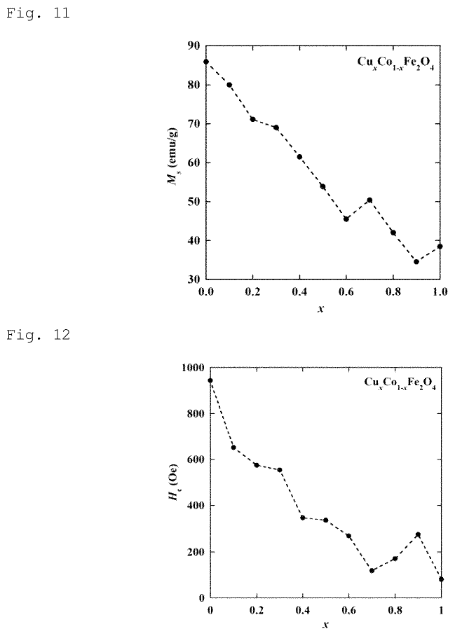

FIG. 10 shows field-magnetization curves of the prepared samples at room temperature. FIGS. 11 and 12 show the plotted values of saturated magnetization Ms and coercive force Hc calculated from the field-magnetization curves.

Saturated magnetization Mₛ of each sample was calculated by approximating Fröhlich's equation to an area near the area in which magnetization M of the field-magnetization curve was saturated. Fröhlich's equation shows a hyperbolic curve and is said to well represent an area from a point around which magnetization M rapidly increases to a point at which magnetization M saturates. Fröhlich's equation is expressed as in Equation (2).

$$y = \frac{H}{a + bH} \qquad Equation ( 2 )$$

Dividing the numerator and denominator of the right-hand side by H transforms Equation (2) into Equation (3).

$$y = \frac{H}{\frac{a}{H} + b} \qquad Equation ( 3 )$$

Saturated magnetization Mₛ is equal to y when applied magnetic field H is made infinite. Thus, taking the limit of H in Equation (3) gives Equation (4).

$$y = \frac{1}{b} \qquad Equation ( 4 )$$

Accordingly, the area from a point around which magnetization M rapidly increased to a point in which magnetization M saturated in the magnetization curve was approximated according to the Fröhlich's equation, and saturated magnetization Mₛ was determined from the obtained b.

FIG. 11 shows that saturated magnetization Mₛ was 85.9 emu/g at x=0.0 and 38.5 emu/g at x=1.0, which were roughly consistent with the values in the literature. Additionally, saturated magnetization Mₛ showed a linear decreasing trend with an increase in the amount of Cu substitution x. CoFe₂O₄ has a reverse spinel structure, with Fe³⁺ occupying most of lattice A, Fe³⁺ occupying half of lattice B, and Co²⁺ occupying the other half. Because the magnetic moment in lattice B and the magnetic moment in lattice A are opposite in the direction due to the super-exchange interaction acting between lattice A and lattice B, the magnetic moment due to Fe³⁺ is cancelled out. Thus, the decrease in saturated magnetization Mₛ of CuₓCo₁₋ₓFe₂O₄ is explained by the substitution of some Co₂₊ with Cu₂₊. However, at x=0.7 and 1.0, saturated magnetization Mₛ is larger than the values expected from the plotted straight lines. In light of the results of X-ray diffraction measurement in FIG. 5, the values of saturated magnetization Mₛ are larger in the compositions in which a heterophase was confirmed. Therefore, the presence of a heterophase that did not fully reacted is thought to have affected saturated magnetization Mₛ.

As shown in FIG. 12, coercive force Hc at x=0.0 was a maximum value of 942 Oₑ. Coercive force Hc also took a local minimum value at x=0.7 and a local maximum value at x=0.9. Coercive force Hc at x=1.0 was a minimum value of 80 Oe.

### Magnetostriction Measurement

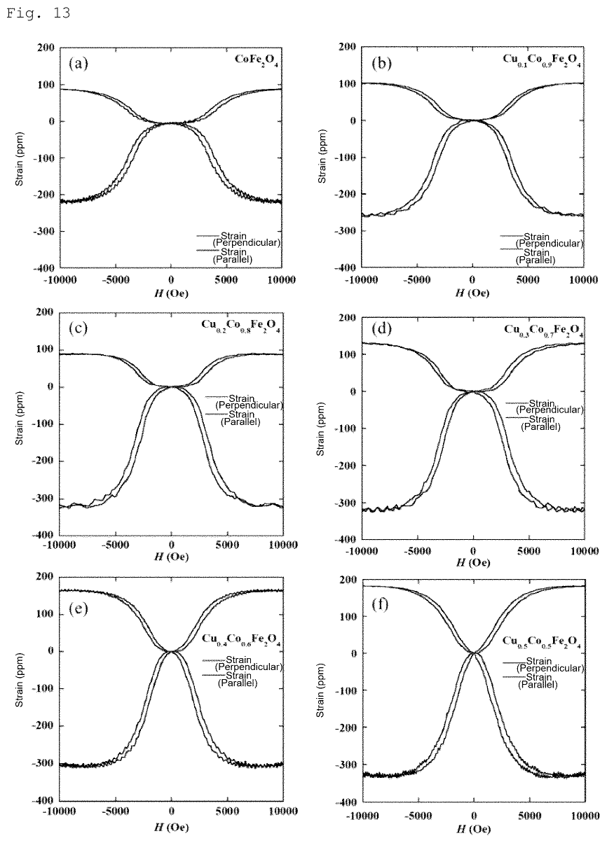

FIGS. 13 and 14 show the results of magnetostriction measurement when the magnetic field applied was −10000≤H(Oe)≤10000.

Magnetostriction constant λₛ was calculated from the results of magnetostriction measurement. In the case of a polycrystal, if the angle made by the direction of an applied magnetic field and the direction of strain measurement is θ, the strain is expressed by Equation (5).

$$\frac{Δ l}{l} = \frac{3}{2} {λ}_{s} ( {cos}^{2} θ - \frac{1}{3} ) \qquad Equation ( 5 )$$

Due to θ being 0, strain λ₈₁ in the direction parallel to the direction of the applied magnetic field is expressed by Equation (6).

$${λ}_{∥} - {λ}_{s} \qquad Equation ( 6 )$$

Due to θ being π/2, the strain in the direction perpendicular to the direction of the applied magnetic field

λ_{⊥}

is expressed by the following:

$${λ}_{⊥} = - \frac{{λ}_{s}}{2} . \qquad Equation ( 7 )$$

Thus, magnetostriction constant λₛ can be expressed using λ₈₁ and

### by Equation (8):

$${λ}_{s} = \frac{2}{3} ( {λ}_{∥} - {λ}_{⊥} ) . \qquad Equation ( 8 )$$

Therefore, Equation (8) was used to calculate magnetostriction constant λₛ. For all compositions, data of λ_{∥} and

λ_{⊥}

at an applied magnetic field of 10000 Oe were used.

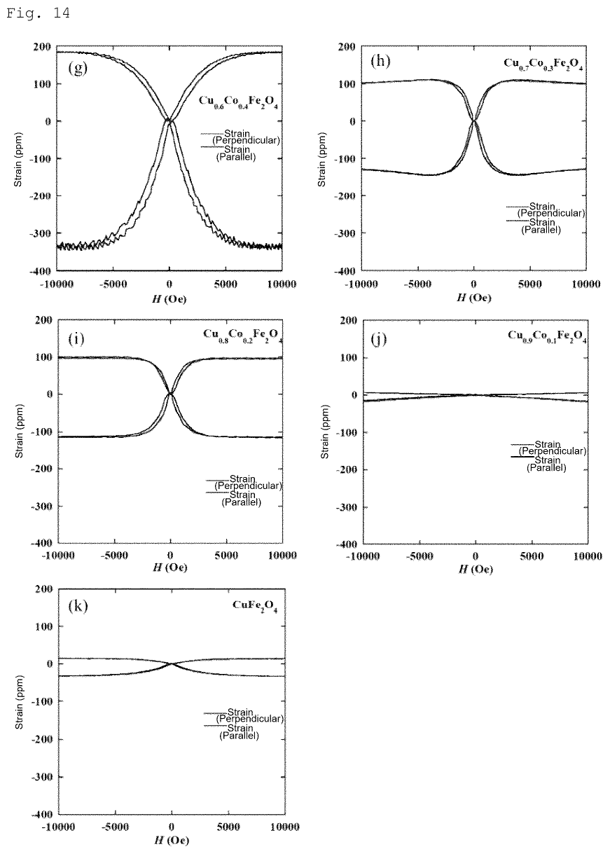

FIG. 15 shows the results with the amount of Cu substitution x on the horizontal axis and calculated magnetostriction constant λₛ (10000 Oe) on the vertical axis. The increase in the absolute value of magnetostriction constant λₛ (10000 Oe) with an increase in the amount of Cu substitution x at x≤0.6 could be due to the Jahn-Teller effect causing a lattice softening phenomenon. Lattice softening is a phenomenon in which the elastic modulus decreases due to the tendency of the lattice present in a cubic crystalline form to distort into a tetragonal form. Similarly, titanium ferrite (TiFe₂O₄), which can undergo lattice softening due to the Jahn-Teller effect, is known to have a large absolute value of magnetostriction constant λₛ, at low temperatures though, as compared with other metal oxide-based materials. Thus, it can be inferred that when Co is partially substituted with Cu, the absolute value of magnetostriction constant λₛ increases while the sample is a cubic crystal, and that the absolute value of magnetostriction constant λₛ decreases when lattice distortion due to the Jahn-Teller effect begins to occur in the crystalline phase of the sample.

Next, the results of magnetostriction measurement at an applied magnetic field of −70000≤H(Oe)≤70000 are shown. With a PPMS, measurement can be performed both under atmospheric pressure and in vacuum. First, whether atmospheric pressure and vacuum would make a significant difference in the measurement was examined. FIG. 16 shows the results of measuring the strain in the direction perpendicular to the applied magnetic field under both conditions for a sample with x=0.0. FIG. 16 indicates that the measurement noise was lower in vacuum. This is thought to be due to the fact that almost no change in the temperature around the sample in vacuum has a decreased effect of temperature change on strain. Based on these results, magnetostriction was measured in vacuum in an applied magnetic field of −70000≤H(Oe)≤ 70000.

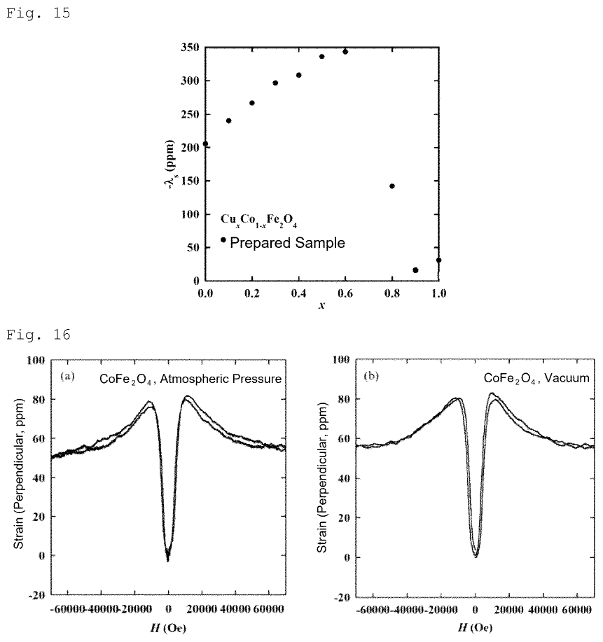

FIG. 17 shows the results of measuring magnetostriction for x=0.0, 0.4, and 0.6 at an applied magnetic field of −70000≈H(Oe)≤70000. The results revealed that in all compositions, the strain was not saturated at a constant level in an applied magnetic field of 1000 Oe, and that strain decreased with an increase in applied magnetic field. Strain was nearly saturated at an applied magnetic field of 70000 Oe. For accurate calculation of magnetostriction constant λₛ using Equation (8), data of λ₈₁ and

λ_{⊥}
at a point at which the strain is constantly saturated must be used. Thus, when investigating the intrinsic magnetostrictive properties of a sample, it is necessary to measure the strain of the sample under application of an intensive magnetic field. Thus, using data of λ₈₁ and
at 70000 Oe, magnetostriction constant λₛ (70000 Oe) was calculated. Values were obtained as the following: −138 ppm for x=0.0, −233 ppm for x=0.4, and −266 ppm for x=0.6. The absolute value for x=0.0 was smaller than 206 ppm, which was the absolute value of magnetostriction constant λₛ (10000 Oe). However, compared to magnetostriction constant λₛ (10000 Oe), magnetostriction constant λₛ (70000 Oe) for x=0.0 was closer to −164 ppm, disclosed in the literature. Given the fact that the sample is porous, it is reasonable enough that due to the density of the sample, the absolute value of magnetostriction constant λₛ (70000 Oe) is smaller than the value in the literature. Since the strain was close to saturation, a more reliable magnetostriction constant λₛ was considered to have been obtained from data of 70000 Oe. Additionally, the absolute values of magnetostriction constant λₛ (70000 Oe) were larger for x=0.4 and x=0.6 than for x=0.0. Thus, the absolute value of magnetostriction constant λₛ of CoFe₂O₄ is clearly larger due to partial substitution of Cu. Additionally, the magnetic susceptibility of strain is increased for x=0.4 and 0.6 as compared with for x=0.0.

Table 4 summarizes the results of measuring the magnetic properties and magnetostrictive properties of the samples of different compositions obtained in the Examples.

TABLE 4

| | | | Magneto- | Magnetos- |
|---|---|---|---|---|
| | Saturated | | striction | triction |
| | Magnetization | | Constant λₛ | Constant λₛ |
| | Mₛ | Coercive Force H_{c} | (10000 Oe) | (70000 Oe) |
| x | (emu/g) | (Oe) | (ppm) | (ppm) |
| 0.0 | 85.9 | 942 | −206 | −138 |
| 0.1 | 80.0 | 651 | −240 | |
| 0.2 | 71.1 | 575 | −267 | |
| 0.3 | 69.0 | 554 | −297 | |
| 0.4 | 61.5 | 347 | −308 | −233 |
| 0.5 | 53.9 | 336 | −336 | |
| 0.6 | 45.5 | 269 | −343 | −266 |
| 0.7 | 50.4 | 117 | −151 | |
| 0.8 | 42.1 | 171 | −142 | |
| 0.9 | 34.5 | 275 | −17.0 | |
| 1.0 | 38.5 | 79.6 | −31.1 | |

### Example 2

### Production of Copper Cobalt Ferrite of Present Invention (Example of Different Starting Material (CuO) and Presence of Other Element)

After the starting materials were weighed and mixed, the sample was sintered into disk-shaped pellets. The pellets were directly measured for magnetostriction. X-ray diffraction measurement was performed with samples prepared by pulverizing the pellets in a mortar. The details of each sample were the same as in Example 1.

To investigate the effect of Zn, a typical element in spinel ferrites, as an example of incorporating other elements, the crystalline structure and magnetostrictive properties of Zn_{z}Cu_{0.5-z}Co_{0.5}Fe₂O₄ were examined. To obtain desired Zn_{z}Cu_{0.5-z}Co_{0.5}Fe₂O₄, α-Fe₂O₃, CuO, CoO, and ZnO were used as starting materials. Table 5 shows the actually used starting materials.

TABLE 5

| Starting | Chemical | | Standard |
|---|---|---|---|
| Material | Formula | Supplier | Value |
| α-Iron(III) Oxide | α-Fe₂O₃ | Rare Metallic Co., Ltd. | 99.999% |
| Copper(II) Oxide | CuO | Wako Pure Chemical | 95.0% |
| | | Industries, Ltd. | |
| Cobalt(II) Oxide | CoO | Wako Pure Chemical | 90.0% or |
| | | Industries, Ltd. | higher |
| Zinc(II) Oxide | ZnO | Wako Pure Chemical | 99.0% |
| | | Industries, Ltd. | |

The procedure of sample preparation is the same as in FIG. 2. Table 6 summarizes the stoichiometric composition of the prepared samples, α-Fe₂O₃, CuO, CoO, and ZnO were weighed so as to have a molar ratio in line with the stoichiometric composition shown in Table 6. The weighed sample, together with zirconia balls and 200 mL of ultrapure water, was placed in a ball mill container made of Teflon (registered trademark), and mixed and pulverized for 2 hours using a pot mill rotating table (Nitto Kagaku Co., Ltd., ANZ-51S). Thereafter, filtration was performed, and the sample on filter paper was taken, dried, and ground with an agate mortar. The ground sample was then pressed into pellets (diameter: 10 mm, thickness: about 2.4 mm) with a manual 100 kN mighty press (MT-100H, NPa System, Co., Ltd.) and sintered in an electric furnace (AS ONE Corporation, high-performance muffle furnace, model number: HPM-0N). The pellets were sintered under the following conditions: air atmosphere, heating time of 5 hours, retention time of 20 hours, cooling time of 5 hours, and sintering temperature of 950° C.

TABLE 6
Stoichiometric Composition

Zn_{z}Cu_{0.5-z}Co_{0.5}Fe₂O₄
(z = 0.0, 0.1, 0.2, 0.3, 0.4, 0.5)

The constituent phases of the obtained powder sample were identified by using a Cu-Kα-ray (λ=0.1541862 nm) laboratory X-ray diffractometer (Rigaku SmartLab SE diffractometer). The measurement was performed at an acceleration voltage of 40 kV, a target current of 30 mA, a 2θ ranging from 20° to 120°, a step width of 0.02°, and a sweep speed of 2°/min. An X-ray diffraction pattern was obtained by taking the diffraction angle 2θ (degrees) on the horizontal axis and the intensity of diffraction lines (counts per second) on the vertical axis.

The Cohen method (B. D. Cullity, Elements of X-Ray Diffraction, second edition, Addison-Wesley Publishing Company (B. D. Cullity, translated by Gentaro Matsumura, Shinban Cullity X-sen Kaisetsu Yoron, Agune Shofusha (1980), pp. 320-337)) was also used for the diffraction pattern obtained in the measurement to calculate the lattice constant of the sample.

### Magnetostriction Measurement

Magnetostriction was measured using a strain gauge (Kyowa Electronic Instruments Co., Ltd., model: KFRB-05-120-C1-11 L1M2R) at room temperature under atmospheric pressure by applying a magnetic field of −10000≤H(Oe)≤10000 by using the same VSM (Toei Industry Co., Ltd., model number: VSM-C7-10) as that used in magnetization measurement. Because the strain gauge must be able to expand and contract in unison with an object to be measured, an instant adhesive for strain gauges (Kyowa Electronic Instruments Co., Ltd., Model: CC-33A) was used for bonding.

### Crystalline Structure of Prepared Sample

### Crystalline Phase Identification

FIG. 18 shows the indexed results of diffraction patterns obtained in X-ray diffraction measurement in the range of 25≤2θ (degrees)≤45. Crystal phase identification revealed that z=0.0 to 0.5 indicates a cubic single phase.

### Calculation of Lattice Constant

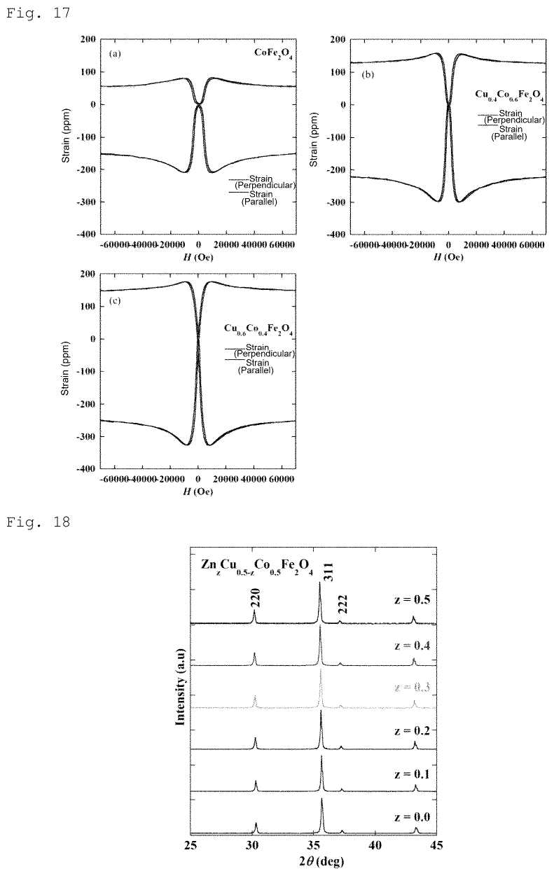

From the patterns obtained in X-ray diffraction measurement, the lattice constant of the major crystalline phases was calculated. FIG. 19 shows the dependence of the lattice constant of Zn_{z}Cu_{0.5-z}Co_{0.5}Fe₂O₄ on the amount of Zn substitution z. The lattice constant is 8.383 Å for the amount of Zn substitution represented z being 0.0, and this value is very close to 8.381 Å, the value for x=0.5 (CuₓCo₁₋ₓFe₂O₄) for the composition shown in Example 1. In this Example, CuO was used as a starting material. Although Cu₂O was used in Example 1, the difference was considered to have little effect on the lattice constant. The lattice constant increases monotonically with an increase in the amount of Zn substitution.

Table 7 summarizes the results of the crystalline phase and lattice constant for samples of different compositions.

TABLE 7

| | | Lattice Constant (Å) |
|---|---|---|
| Z | Crystalline Phase | a, b, c |
| 0.0 | Cubic Crystal | 8.383 |
| 0.1 | Cubic Crystal | 8.392 |
| 0.2 | Cubic Crystal | 8.393 |
| 0.3 | Cubic Crystal | 8.401 |
| 0.4 | Cubic Crystal | 8.408 |
| 0.5 | Cubic Crystal | 8.416 |

### Magnetostriction Measurement

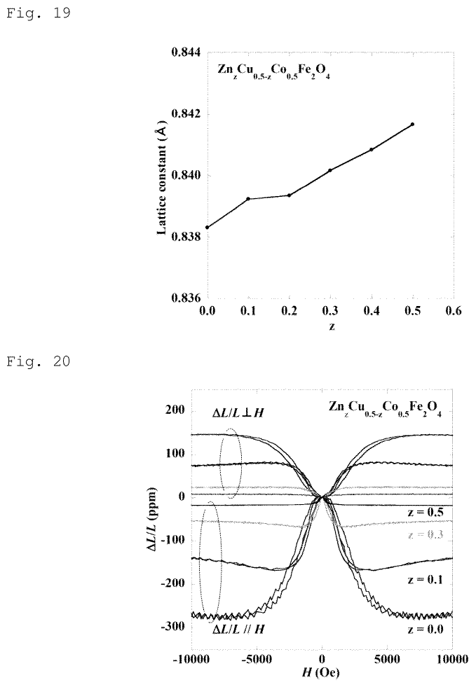

FIG. 20 shows the results of magnetostriction measurement when the applied magnetic field was θ10000≤H(Oe)≤10000.

Magnetostriction constant λₛ was calculated from the results of magnetostriction measurement. Equation (8) was used to calculate magnetostriction constant λₛ. For all compositions, data used were of λ₈₁ and

λ_{⊥}

at an applied magnetic field of 10000 Oe.

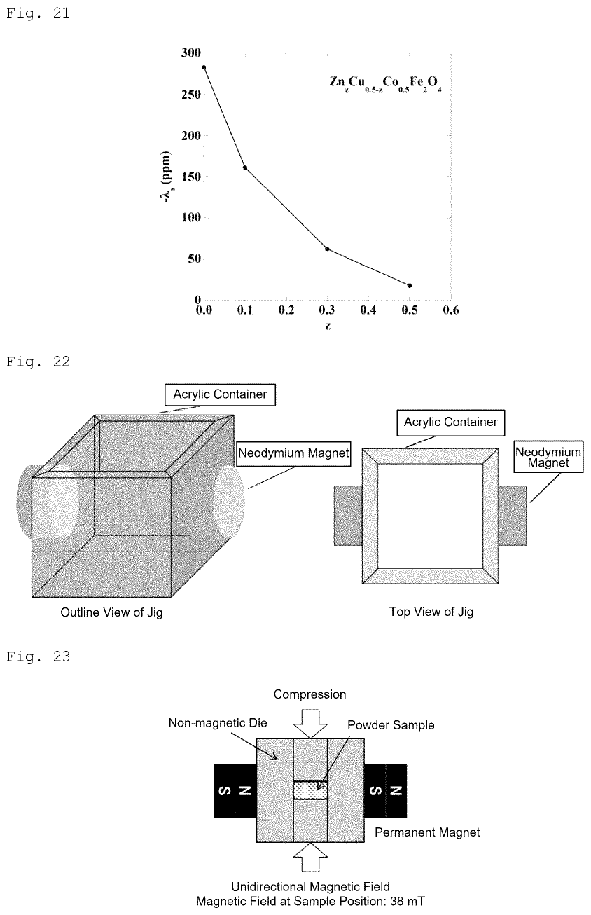

FIG. 21 shows the results, in which the amount of Zn substitution z is on the horizontal axis, and calculated magnetostriction constant λₛ (10000 Oₑ) is on the vertical axis. Magnetostriction constant λₛ for the amount of Zn substitution z being 0.0 is-282 ppm, which is smaller than the absolute value (λₛ=−336) for x=0.5 for the composition shown in Example 1 (cuₓCo₁₋ₓFe₂O₄), but much larger than the absolute value (λₛ=−206) for x=0.0. In this Example, CuO was used as a starting material, whereas Cu₂O was used in Example 1. That is, copper cobalt ferrites show excellent magnetostrictive properties regardless of which starting material is used for preparing the copper cobalt ferrites. As shown in FIG. 21, the absolute value of magnetostriction constant λₛ decreases monotonically with an increase in the amount of Zn substitution. However, the magnetostriction curve of Zn substitution z=0.1 shown in FIG. 20 indicates that the magnetic susceptibility of strain is higher than that of z=0.0. Thus, excellent magnetostrictive properties are obtained even after partial substitution with Zn.

Table 8 summarizes the results of measuring the magnetostrictive properties of the samples of different compositions obtained in this Example.

TABLE 8

| | Magnetostriction |
|---|---|
| | Constant λₛ (10000 Oe) |
| z | (ppm) |
| 0.0 | −282 |
| 0.1 | −161 |
| 0.2 | — |
| 0.3 | −62 |
| 0.4 | — |
| 0.5 | −17 |

### Example 3

### Preparation of Starting Powder for Magnetic-Field-Applied Compact Powder

Starting materials were weighed and mixed in a ratio of stoichiometric composition of Cu_{0.5}Co_{0.5}Fe₂O₄ and then compacted into disk-shaped pellets and sintered. The details of the raw materials used as starting materials were the same as those in Example 1. Sintering was performed under the following conditions: air atmosphere, heating time of 5 hours, retention time of 10 hours, cooling time of 5 hours, and sintering temperature of 950° C. The obtained sintered pellets were pulverized in a mortar and prepared as a starting powder for magnetic-field-applied compact powder samples. The starting powder was identified by X-ray diffraction measurement as being composed of a single phase of cubic crystals with a spinel structure.

TABLE 9
Stoichiometric Composition

Cu_{0.5}Co_{0.5}Fe₂O₄

Jig for Forming Magnetic-field-applied Compact Powder

A jig for applying a magnetic field was fabricated by bonding a neodymium magnet to a set of opposite sides of an acrylic square cylinder with an open top and an open bottom. FIG. 22 shows an image of the jig. A non-magnetic die was inserted into the cavity of the jig, and a magnetic field was applied to the position of a sample on the die.

### Preparation of Compact Powder Sample in Unidirectional Magnetic Field

675 mg of the starting powder was placed in a 10 mL small beaker, and 1.5 mL of ultrapure water was added thereto, followed by stirring with an ultrasonic generator for about 20 seconds, thereby preparing a slurry. The jig shown in FIG. 22 was attached to a non-magnetic die, and the slurry was poured with a unidirectional magnetic field applied to the die at the position of the sample. The magnitude of the magnetic field applied to the position of the sample on the die was about 38 mT. The slurry was pressed by using a hydraulic press (Rikenkiki Co., Ltd., P-1B) with a unidirectional magnetic field applied, thereby obtaining plate-shaped pellets (10×10 mm, thickness: about 2 mm). FIG. 23 shows an image. The plate-shaped pellets were sintered under the following conditions: air atmosphere, heating time 5 hours, retention time 10 hours, cooling time 5 hours, and sintering temperature 950° C., thereby obtaining a unidirectional magnetic-field applied compact powder sample.

### Preparation of Compact Powder Sample in Rotating Magnetic Field

600 mg of preliminarily sintered powder was placed in a 10 mL small beaker, and 1.5 mL of ultrapure water was added thereto, followed by stirring with an ultrasonic generator for about 20 seconds, thereby preparing a slurry. The jig shown in FIG. 22 was attached to a non-magnetic die, and the slurry was poured with a unidirectional magnetic field applied to the sample position on the die. The magnitude of the magnetic field applied to the sample position was 46 mT. With the non-magnetic die fixed, the jig was rotated clockwise (once per second for about one minute), and the sample was pressed by using a hydraulic press (Rikenkiki Co., Ltd., P-1B) with a rotating magnetic field applied to the sample, thereby obtaining disk-shaped pellets (diameter: 10 mm, thickness: about 2 mm). FIG. 24 shows an image. The disk-shaped pellets were sintered under the following conditions: air atmosphere, heating time of 5 hours, retention time of 10 hours, cooling time of 5 hours, and sintering temperature of 950° C., thereby obtaining a rotating-magnetic-field applied compact powder sample.

### Magnetostriction Measurement

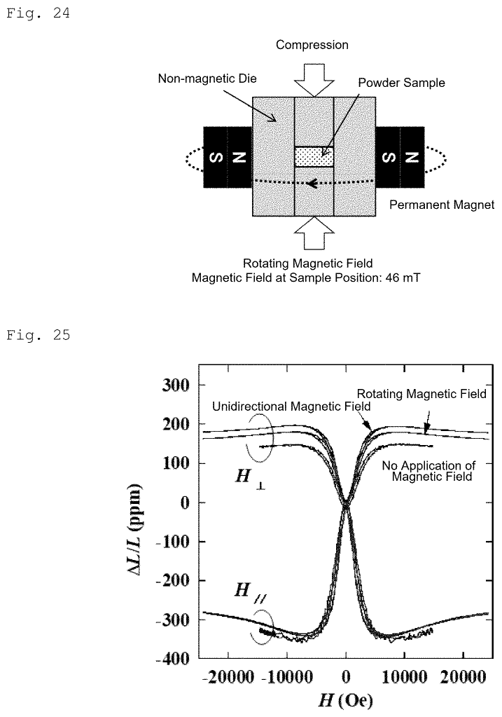

FIG. 25 shows the results of measuring magnetostriction. The magnetostriction of the samples prepared by applying a unidirectional magnetic field or a rotating magnetic field was measured at an applied magnetic field of −25000≤H(Oₑ)≤25000. For comparison, the results are also shown for a sample prepared by compacting powder without application of a magnetic field.

In the magnetostriction curve obtained by applying a magnetic field parallel (H_{//}) to the direction of strain measurement, ΔL/L of the samples prepared by applying a unidirectional magnetic field or a rotating magnetic field indicates the absolute values equivalent to the value of the sample prepared with no magnetic field applied. On the other hand, in the magnetostriction curve obtained by applying a magnetic field perpendicular (H_{⊥}) to the direction of strain measurement, ΔL/L of the samples prepared by applying a unidirectional magnetic field or a rotating magnetic field indicates larger absolute values than the value of the sample prepared with no magnetic field applied. As a result, the difference in ΔL/L between H_{//}and H₁₉₅ (ΔL/L_{//}-ΔL/L_{⊥}) of the samples prepared by applying a unidirectional magnetic field or a rotating magnetic field is larger in absolute value than of the sample prepared with no magnetic field applied. In other words, magnetostrictive properties are improved by forming a polycrystalline powder sample by compacting power in a unidirectional magnetic field or in a rotating magnetic field.

### Example 4

### Production of Copper Cobalt Ferrite of The Present Invention (Example of Incorporation of Mn)

Starting materials were weighed and mixed and then sintered into a disk-shaped pellet sample. Magnetostriction was measured with the pellets. X-ray diffraction measurement was performed on a sample prepared by pulverizing the pellets in a mortar. The details of each are the same as in Example 1.

To investigate the effect of incorporated Mn, the crystalline structure and magnetostrictive properties of Cu_{0.5}Co_{0.5}Mn_{w}Fe_{2-w}O₄ were examined. To obtain desired Cu_{0.5}Co_{0.5}Mn_{w}Fe_{2-w}O₄, α-Fe₂O₃, Cu₂O, CoO, and Mn₂O₃ were used as starting materials. Table 10 shows the actually used raw materials.

TABLE 10

| | Chemical | | Standard |
|---|---|---|---|
| Raw Material | Formula | Supplier | Value |
| α-Iron(III) Oxide | α-Fe₂O₃ | Rare Metallic Co., Ltd. | 99.999% |
| Cupper(I) Oxide | Cu₂O | Wako Pure Chemical | 99.5% or |
| | | Industries, Ltd. | higher |
| Cobalt(II) Oxide | CoO | Wako Pure Chemical | 90.0% or |
| | | Industries, Ltd. | higher |
| Manganese (III) Oxide | Mn₂O₃ | Strem Chemicals | 99% |

The procedure of sample preparation is the same as in FIG. 2. Table 11 summarizes the stoichiometric composition of the prepared samples, α-Fe₂O₃, Cu₂O, CoO, and Mn₂O₃ were weighed so as to have a molar ratio in line with the stoichiometric composition shown in Table 11. The weighed sample, together with zirconia balls and 200 mL of ultrapure water, was placed in a ball mill container made of Teflon (registered trademark), and mixed and pulverized for 2 hours using a pot mill rotating table (Nitto Kagaku Co., Ltd., ANZ-51S). Thereafter, filtration was performed, and the sample on filter paper was taken, dried, and ground with an agate mortar. The ground sample was then pressed into pellets with a hydraulic press (Rikenkiki Co., Ltd., P-1B) and sintered in an electric furnace (AS ONE Corporation, high-performance muffle furnace, model number: HPM-0N). The pellets were sintered under the following conditions: air atmosphere, heating time of 5 hours, retention time of 20 hours, cooling time of 5 hours, and sintering temperature of 950° C.

TABLE 11
Stoichiometric Composition

Cu_{0.5}Co_{0.5}Mn_{w}Fe_{2-w}O₄
(w = 0.00, 0.05, 0.10, 0.15, 0.20, 0.40, 1.00)

The constituent phases of the obtained powder sample were identified by using a Cu-Kα-ray (λ=0.1541862 nm) laboratory X-ray diffractometer (Rigaku SmartLab SE diffractometer). The measurement was performed at an acceleration voltage of 40 kV, a target current of 30 mA, a 2θ ranging from 20° to 120°, a step width of 0.02°, and a sweep speed of 2°/min. An X-ray diffraction pattern was obtained by taking the diffraction angle 2θ (degrees) on the horizontal axis and the intensity of diffraction lines on the vertical axis.

The Cohen method (B. D. Cullity, Elements of X-Ray Diffraction, second edition, Addison-Wesley Publishing Company (B. D. Cullity, translated by Gentaro Matsumura, Shinban Cullity X-sen Kaisetsu Yoron, Agune Shofusha (1980), pp. 320-337)) was also used for the diffraction pattern obtained in the measurement to calculate the lattice constant of the sample.

### Magnetostriction Measurement

For magnetostriction measurement, a strain gauge (Kyowa Electronic Instruments Co., Ltd., model: KFRB-05-120-C1-11 L1M3R) and instant adhesive for a strain gauge (Kyowa Electronic Instruments Co., Ltd., model: CC-33A) were used. Magnetostriction was measured at room temperature under atmospheric pressure by applying a magnetic field of −10000≤H(Oe)≤10000 by using a VSM (Toei Industry Co., Ltd., model number: VSM-C7-10).

### Crystalline Structure of Prepared Sample

### Crystalline Phase Identification

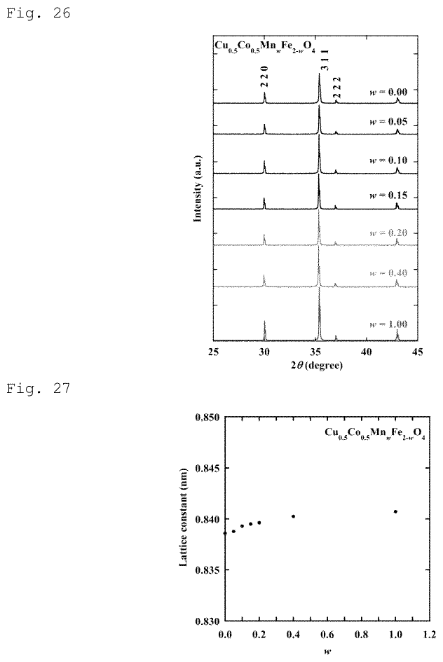

FIG. 26 shows the indexed results of diffraction patterns obtained in X-ray diffraction measurement in the range 25≤2θ (degrees)≤45. Crystal phase identification revealed that 0.00≤w≤1.00 indicates a single phase of cubic crystals.

### Calculation of Lattice Constant

From the patterns obtained in X-ray diffraction measurement, the lattice constant of the cubic crystalline phase of Cu_{0.5}Co_{0.5}Mn_{w}Fe_{z-w}O₄ was calculated. FIG. 27 shows the dependence of the lattice constant on the amount of Mn substitution w. The lattice constant increases with an increase in the amount of Mn substitution w.

Table 12 summarizes the results of the crystalline phases and lattice constant of the samples of different compositions.

TABLE 12

| w | Crystalline Phase | Lattice Constant (Å) |
|---|---|---|
| 0.00 | Cubic Crystal | 8.386 |
| 0.05 | Cubic Crystal | 8.388 |
| 0.10 | Cubic Crystal | 8.393 |
| 0.15 | Cubic Crystal | 8.395 |
| 0.20 | Cubic Crystal | 8.396 |
| 0.40 | Cubic Crystal | 8.403 |
| 1.00 | Cubic Crystal | 8.407 |

### Magnetostriction Measurement

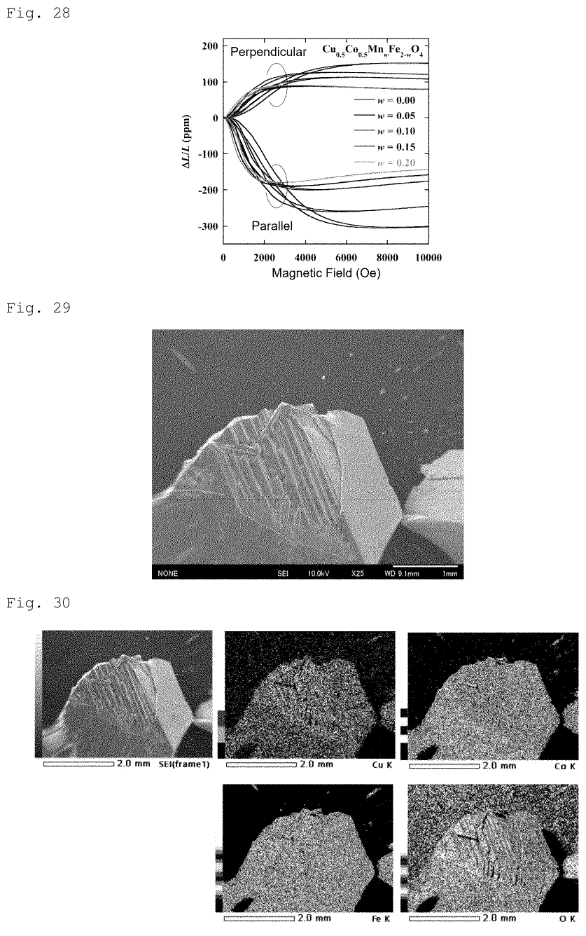

FIG. 28 shows the magnetostriction curves of Cu_{0.5}CO_{0.5}Mn_{w}Fe_{2-w}O₄ at room temperature. A magnetic field was applied in the direction parallel and perpendicular to the measurement direction for strain ΔL/L. In the magnetostriction curves for magnetic field applied in the parallel and perpendicular directions, the absolute value of ΔL/L at 10000 Oe decreases with an increase in the amount of Mn substitution. However, when compared, for example, at 2000 Oₑ, the absolute values of the amount of strain ΔL/L for the samples with partial Mn substitution (w=0.05, 0.10, 0.15, 0.20) are larger than that for w=0.00. In other words, partial Mn substitution improves magnetic susceptibility of strain in a magnetostriction curve and improves magnetostrictive properties in a low magnetic field range.

### Example 5

### Preparation of Monocrystal of Copper Cobalt Ferrite by Flux Method

To obtain a monocrystal of copper cobalt ferrite, α-Fe₂O₃, Cu₂O, and CoO were used as starting materials, and NaB₄O₇·10H₂O was used as flux. CoO with a purity of at least 90.0% was used. Table 13 shows the actually used raw materials and flux.

TABLE 13

| Raw Material | Chemical | | Standard |
|---|---|---|---|
| and Flux | Formula | Supplier | Value |
| α-Iron(III) Oxide | α-Fe₂O₃ | Rare Metallic Co., | 99.999% |
| | | Ltd. | |
| Cupper(I) Oxide | Cu₂O | Wako Pure Chemical | 99.5% or |
| | | Industries, Ltd. | higher |
| Cobalt(II) Oxide | CoO | Wako Pure Chemical | 90.0% or |
| | | Industries, Ltd. | higher |
| Sodium | NaB₄O₇•10H₂O | Wako Pure Chemical | 99.5 to |
| Tetraborate | | Industries, Ltd. | 101.0% |
| Decahydrate | | | |

10 g of NaB₄O₇·10H₂O, and α-Fe₂O₃, Cu₂O, and CoO were weighed so as to have a molar ratio in line with the stoichiometric composition shown in Table 14, and placed in a crucible made of platinum (product name: PT crucible with a lid, figure number: 56-PT-1030C, Tanaka Kikinzoku Kogyo). The raw materials and flux were mixed uniformly with a medicine spoon, covered with the lid, and sintered in an electric furnace (Yamada Denki Co., Ltd., tabletop high-speed-heating electric furnace, model: MSFT-1020). The sintering conditions were as shown in Table 15, and sintering was performed in six steps. All of the sintering steps were performed in an air atmosphere.

After sintering, the obtained sample was placed in a small beaker together with the crucible, and a 20% aqueous nitric acid solution was poured into the beaker until the crucible was submerged. The small beaker was placed in a container filled with water, and the container was placed on a hot magnetic stirrer (IKA, model: C-MAG HS4 S27), followed by heating. This allows the inside of the small beaker to be warmed by a hot water bath. The temperature of the hot magnetic stirrer was set so as to keep the water in the container at around 70° C. This condition was maintained for 5 to 10 days, and the dissolution of the flux in the small beaker and the removal of the crystals adhering to the inside of the crucible were confirmed, followed by filtration. Because the flux was soluble in nitric acid, only crystals remained on the filter paper. After ultrapure water was repeatedly poured over the filter paper to ensure that the pH of the filtered ultrapure water was neutral, the crystals were collected. The collected crystals were washed with acetone to remove fine crystal grains around the crystals and residual flux.

The crystals obtained according to the method above were present down to a size of about 4 mm.

TABLE 14
Stoichiometric Composition

Cu_{0.5}Co_{0.5}Fe₂O₄

TABLE 15

| Step | Sintering Conditions |
|---|---|
| 1 | Heating to 1350° C. at 100° C./h |
| 2 | Maintaining at 1350° C. for 5 h |
| 3 | Cooling to 1200° C. at 2° C./h |
| 4 | Cooling to 1100° C. at 3° C./h |
| 5 | Cooling to 1000° C. at 5° C./h |
| 6 | Cooling Furnace to Room Temperature |

Electron-microscopic Observation and Elemental Analysis A scanning microscope (SEM, JSM-7000F) was used for electron-microscopic observation and elemental analysis of the prepared samples. Elemental mapping and quantitative analysis of the sample composition were performed according to EDX (energy dispersive X-ray spectroscopy).

FIG. 29 shows the results of electron-microscopic observation of a prepared sample. A typical field of view of a sample obtained according to the flux method was selected as an example. Facets were observed in some parts of the sample, suggesting that the sample was a monocrystal. FIG. 30 shows the elemental mapping results for Cu, Co, Fe, and O of a prepared sample. The distribution of Cu, Co, and Fe was observed throughout the sample. The quantitative analysis of the elements indicated that the composition of the obtained sample was approximately Cu_{0.21}Co_{0.64}Fe_{2.1}O₄. Although the composition differed from the stoichiometric composition of the starting materials, the formation of ferrite containing Cu, Co, and Fe was confirmed.

### X-ray Diffraction Measurement of Prepared Sample

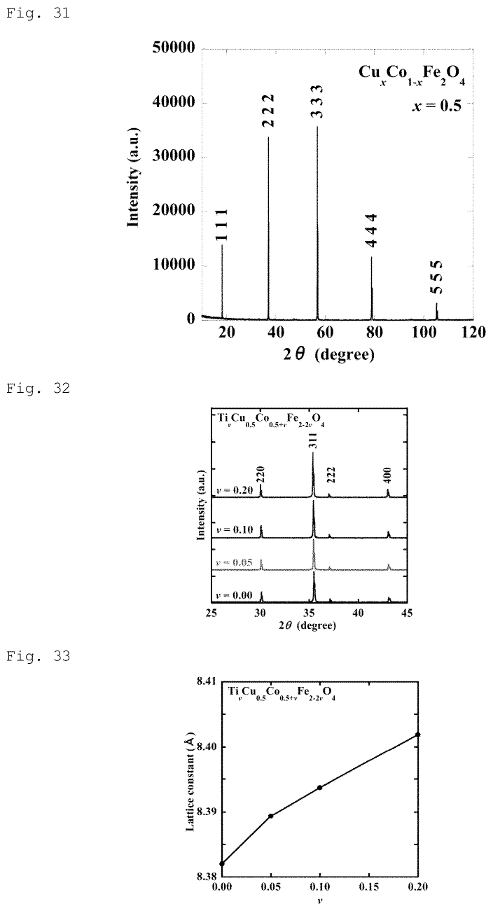

FIG. 31 shows the indexed results of diffraction patterns obtained in X-ray diffraction measurement in the range of 10≤2θ (degrees)≤120. The principle of X-ray structural analysis is the same as that shown in Example 1. Diffraction peaks of (111), (222), (333), (444), and (555) planes of a cubic crystal with a spinel structure were observed, and no other diffraction peaks were observed. In other words, the obtained sample was a monocrystal formed of a single phase of cubic crystals with a spinel structure. In light of the results of elemental analysis above, it was clear that a monocrystal of CuₓCo₁₋ₓFe_{z}O₄ can be made according to the flux method.

### Example 6

### Production of Copper Cobalt Ferrite of The Present Invention (Example of Incorporation of Ti)

Starting materials were weighed and mixed and then sintered into a disk-shaped pellet sample. Magnetostriction was measured with the pellets. X-ray diffraction measurement was performed on a sample prepared by pulverizing the pellets in a mortar. The details of each are the same as in Example 1.

To investigate the effect of incorporated Ti, the crystalline structure and magnetostrictive properties of TiᵥCu_{0.5}Co_{0.5+v}Fe₂₋₂ᵥO₄ were examined. To obtain desired TiᵥCu_{0.5}CO_{0.5+v}Fe₂₋₂ᵥO₄, α-Fe₂O₃, CuO, CoO, and TiO₂ were used as starting materials. Table 16 shows the actually used raw materials.

TABLE 16

| | Chemical | | Standard |
|---|---|---|---|
| Raw Material | Formula | Supplier | Value |
| α-Iron(III) Oxide | α-Fe₂O₃ | Rare Metallic Co., Ltd. | 99.999% |
| Cupper(I) Oxide | Cu₂O | Wako Pure Chemical | 99.5% or |
| | | Industries, Ltd. | higher |
| Cobalt(II) Oxide | CoO | Wako Pure Chemical | 90.0% or |
| | | Industries, Ltd. | higher |
| Titanium(IV) Oxide | TiO₂ | Rare Metallic Co. Ltd. | 99.99% |

The procedure of sample preparation is the same as in FIG. 2. Table 17 summarizes the stoichiometric composition of the prepared samples, α-Fe₂O₃, CuO, CoO, and TiO₂ were weighed so as to have a molar ratio in line with the stoichiometric composition shown in Table 17. The weighed sample, together with zirconia balls and 200 mL of ultrapure water, was placed in a ball mill container made of Teflon (registered trademark), and mixed and pulverized for 2 hours using a pot mill rotating table (Nitto Kagaku Co., Ltd., ANZ-51S). Thereafter, filtration was performed, and the sample on filter paper was taken, dried, and ground with an agate mortar. The ground sample was then pressed into pellets with a hydraulic press (Rikenkiki Co., Ltd., P-1B) and sintered in an electric furnace (AS ONE Corporation, high-performance muffle furnace, model number: HPM-0N). The pellets were sintered under the following conditions: air atmosphere, heating time of 5 hours, retention time of 20 hours, cooling time of 5 hours, and sintering temperature of 950° C.

TABLE 17
Stoichiometric Composition

TiᵥCu_{0.5}Co_{0.5+v}Fe₂₋₂ᵥO₄
(v = 0.00, 0.05, 0.10, 0.20)

The constituent phases of the obtained powder sample were identified by using a Cu-Kα-ray (Δ=0.1541862 nm) laboratory X-ray diffractometer (Rigaku SmartLab SE diffractometer). The measurement was performed at an acceleration voltage of 40 kV, a target current of 30 mA, a 2θ ranging from 20° to 120°, a step width of 0.02°, and a sweep speed of 2°/min. An X-ray diffraction pattern was obtained by taking the diffraction angle 2θ (degrees) on the horizontal axis and the intensity of diffraction lines on the vertical axis.

The Cohen method (B. D. Cullity, Elements of X-Ray Diffraction, second edition, Addison-Wesley Publishing Company (B. D. Cullity, translated by Gentaro Matsumura, Shinban Cullity X-sen Kaisetsu Yoron, Agune Shofusha (1980), pp. 320-337)) was also used for the diffraction pattern obtained in the measurement to calculate the lattice constant of the sample.

Magnetostriction Measurement For magnetostriction measurement, a strain gauge (Kyowa Electronic Instruments Co., Ltd., model: KFRB-05-120-C1-11 L1M3R) and instant adhesive for a strain gauge (Kyowa Electronic Instruments Co., Ltd., Model: CC-33A) were used. Magnetostriction was measured at room temperature under atmospheric pressure by applying a magnetic field of −25000≤H(Oₑ)≤25000 by using a VSM.

### Crystalline Structure of Prepared Sample

### Crystalline Phase Identification

FIG. 32 shows a magnified view of the diffraction patterns obtained in X-ray diffraction measurement of each composition in the range 25°≤2θ (degrees)≤45°. All of the diffraction peaks were able to be indexed with a cubic crystal of a spinel structure, and no diffraction peaks other than those of a cubic crystal with a spinel structure were observed. This indicates a single phase of cubic crystal with a spinel structure in all of the compositions.

### Calculation of Lattice Constant

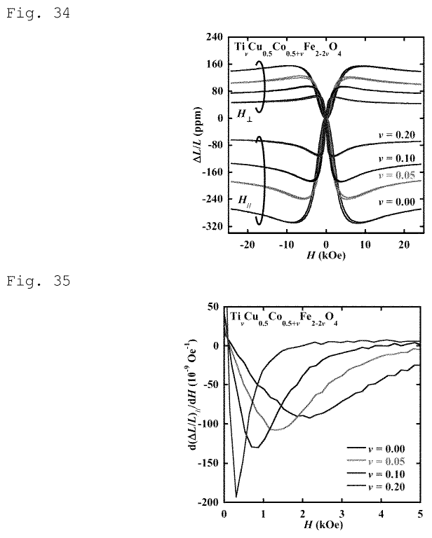

From the patterns obtained in X-ray diffraction measurement, the lattice constant of the cubic crystalline phase of TiᵥCu_{0.5}Co_{0.5+v}Fe₂₋₂ᵥO₄ was calculated. FIG. 33 shows the dependence of the lattice constant on the amount of Ti substitution v. The lattice constant increases with an increase in the amount of Ti substitution v.

### Magnetostriction Measurement

FIG. 34 shows the magnetostriction curves of TiᵥCu_{0.5}CO_{0.5+v}Fe₂₋₂ᵥO₄ at room temperature. A magnetic field was applied in the direction parallel and perpendicular to the measurement direction for strain ΔL/L. In the magnetostriction curves of magnetic fields applied in the parallel and perpendicular directions, the absolute value of ΔL/L at the maximum magnetic field applied decreases with an increase in the amount of Ti substitution.

FIG. 35 shows the magnetic field dependence of magnetic susceptibility of strain (dΔL/L/dH) obtained by differentiating the magnetostriction curves in the magnetic field application process during the parallel magnetic field application in FIG. 34. Due to partial Ti substitution, the local maximum of magnetic susceptibility of strain occurs in a low magnetic field. Additionally, the maximum value of magnetic susceptibility of strain also increases along with partial Ti substitution. In other words, partial Ti substitution improves magnetostrictive properties in a low-magnetic-field region.

1. A magnetostrictive material comprising a copper cobalt ferrite containing a cubic crystal as a primary crystalline phase.

2. The magnetostrictive material according to claim 1, wherein the copper cobalt ferrite consists essentially of a cubic phase.

3. The magnetostrictive material according to claim 1, wherein the copper cobalt ferrite is represented by CuₓCo_{y-x}Fe_{3-y}O₄ (0<x/y≤0.75 and 0.8≤y≤1.2), with the proviso that one or more elements among Co, Fe, and Cu may further be partially substituted with one or more other elements.

4. The magnetostrictive material according to claim 1, which is a polycrystal or a monocrystal.

5. The magnetostrictive material according to claim 4, wherein the polycrystal is a non-oriented polycrystal.

6. The magnetostrictive material according to claim 4, wherein the polycrystal is a crystallographically oriented polycrystal.

7. An element being operative by using a magnetostriction effect or an inverse magnetostriction effect of the magnetostrictive material of claim 1.

8. The element according to claim 7, which is a transducer, an actuator, a sensor, or a vibration-powered generator.

9. A method for operating an element containing the magnetostrictive material of claim 1, comprising the step of operating the element by using a magnetostriction effect or an inverse magnetostriction effect of the magnetostrictive material.

10. A method for producing a copper cobalt ferrite containing a cubic crystal as a primary crystalline phase, comprising the step of producing the copper cobalt ferrite by using iron oxide, copper oxide, and cobalt oxide as starting materials.

11. The method according to claim 10,
wherein the copper cobalt ferrite is represented by a chemical formula: CuₓCo_{y-x}Fe_{3-y}O₄ (0<x/y≤0.75 and 0.8≤y≤1.2), with the proviso that one or more elements among Co, Fe, and Cu may further be partially substituted with one or more other elements,
the method further comprising the step of adjusting the molar ratio of the starting materials to a stoichiometric composition based on the chemical formula to obtain the copper cobalt ferrite.
